(19) United States
(12) Patent Application Publication
(10) Pub. No.: US 2006/0239056 A1
(43) Pub. Date: Oct. 26, 2006

(54) Generation of MRAM programming currents using external capacitors

(76) Inventors: Dietmar Gogl, Essex Junction, VT (US); Hans-Heinrich Viehmann, Munich (DE); Daniel Braun, Paris (FR)

Correspondence Address: SLATER & MATSIL LLP, 17950 PRESTON ROAD, SUITE 1000, DALLAS, TX, 75252, US

(21) Appl. No.: 11/112,851

(22) Filed: Apr. 22, 2005

(51) Int. Cl. G11C 5/00

(52) U.S. Cl. 365/52

(57) ABSTRACT

An apparatus comprising a magnetoresistive random access memory (MRAM) and a method of forming the same. The apparatus includes a memory circuit comprising an MRAM cell, and a charge pump circuit electrically coupled to the memory circuit wherein the memory circuit and at least a first portion of the charge pump circuit are fabricated on a single semiconductor chip. The charge pump circuit further includes a second portion comprising at least one capacitor external to the semiconductor chip. The second portion of the charge pump circuit may be packaged in a chip package or external to the chip package.

### TECHNICAL FIELD

The present invention relates generally to semiconductor memory devices, and more particularly to charge pumps used in programming circuit of magnetoresistive random access memory (MRAM) devices and methods of manufacture thereof.

### BACKGROUND

Semiconductors are used in integrated circuits for electronic applications, including radios, televisions, cell phones, and personal computing devices, as examples. One type of semiconductor device is a semiconductor storage device, such as a dynamic random access memory (DRAM) or a flash memory, both of which use charge to store information.

A more recent development in semiconductor memory devices involves spin electronics, which combines semiconductor technology and magnetic materials and devices. The spins of electrons, through their magnetic moments, rather than the charge of the electrons, is used to indicate the presence of a “1” or “0”. One such spin electronic device is a magnetoresistive random access memory (MRAM) device 100, sometimes referred to as a magnetic RAM, as shown in FIG. 1, which includes conductive lines (wordlines WL and bitlines BL) positioned in a different direction, e.g., perpendicular to one another in different metal layers, the conductive lines sandwiching a magnetic stack or magnetic tunnel junction (MTJ) 102, which functions as a magnetic memory cell. FIG. 1 shows a perspective view of a portion of a prior art cross-point MRAM array 100. The MRAM device 100 includes a semiconductor wafer comprising a workpiece (not shown). The workpiece has a first insulating layer (also not shown) deposited thereon, and a plurality of first conductive lines or wordlines WL is formed within the first insulating layer, e.g., in a first wiring level.

In a cross-point magnetic memory device 100, each memory cell or magnetic tunnel junction (MTJ) 102 is disposed over and abuts one wordline WL, as shown. The MTJ 102 of a magnetoresistive memory comprises three layers: ML1, TL and ML2. The MTJ 102 includes a first magnetic layer ML1 disposed over and abutting the wordline WL. The first magnetic layer ML1 is often referred to as a fixed layer because its magnetic orientation is fixed. A tunnel layer or tunnel barrier layer TL comprising a thin dielectric layer is formed over the fixed layer ML1. A second magnetic layer ML2 is formed over the tunnel barrier layer TL. The second magnetic layer ML2 is often referred to as a free layer because its magnetic orientation can be switched along one of two directions. The first and second magnetic layers ML1 and ML2 may comprise one or more material layers, for example.

Each MTJ 102 has a second conductive line or bitline BL disposed over and abutting the second magnetic layer ML2, as shown in FIG. 1, wherein the bitline BL is positioned in a direction different from the direction of the wordline WL, e.g., the bitlines BL may be orthogonal to the wordlines WL. An array 100 of magnetic memory cells 102 comprises a plurality of wordlines WL running parallel to one another in a first direction, a plurality of bitlines BL running parallel to one another in a second direction, the second direction being different from the first direction, and a plurality of MTJ's 102 disposed between each wordline WL and bitline BL. While the bitlines BL are shown on top and the wordlines WL are shown on bottom of the array 100, alternatively, the wordlines WL may be disposed on the top of the array and the bitlines BL may be disposed on the bottom of the array, for example.

Either one of the first or second magnetic layers ML1 and ML2 may comprise a hard magnetic material (and is the fixed layer), and the other comprises a soft magnetic material (and is the free layer), although in the discussion herein, the first magnetic layer ML1 comprises the hard magnetic material, and the second magnetic layer ML2 comprises the soft magnetic material. The value of the resistance of the cell or MTJ 102 depends on the way in which the magnetic moment of the soft magnetic layer ML2 is oriented in relation to the magnetic moment of the hard magnetic layer ML1. The resistance of the magnetic memory cell 102 depends on the moment's relative alignment. The resistance R_{C} is usually lower if the magnetic layers have parallel magnetic orientations. For example, if the first and second magnetic layers ML1 and ML2 are oriented in the same direction, as shown in FIG. 2B, the cell resistance Rc is low. If the first and second magnetic layers ML1 and ML2 are oriented in opposite directions, shown in FIG. 2C, the cell resistance Rc is high. These two states of the cell are used to store digital information (a logic “1” or “0”, high or low resistance, or vice versa).

The hard magnetic layer ML1 is usually oriented once during manufacturing. The information of the cell 102 is stored in the soft magnetic layer ML2. As shown in FIG. 2A, the currents I_{WL} and I_{BL} through the wordline WL and bitline BL, respectively, provide the magnetic field that is necessary to store information in the soft magnetic layer ML2. The superimposed magnetic fields of the bitline BL and wordline WL currents have the ability to switch the magnetic moment of the soft magnetic layer ML2 and change the memory state of the cell 102.

An advantage of MRAM devices compared to traditional semiconductor memory devices such as dynamic random access memory (DRAM) devices is that MRAM devices are non-volatile. For example, a personal computer (PC) utilizing MRAM devices would not have a long “boot-up” time as with conventional PCs that utilize DRAM devices. Also, an MRAM device does not need to be powered up and has the capability of “remembering” the stored data (also referred to as a non-volatile memory). MRAM devices have the capability to provide the density of DRAM devices and the speed of static random access memory (SRAM) devices, in addition to non-volatility. Therefore, MRAM devices have the potential to replace flash memory, DRAM and SRAM devices in electronic applications where memory devices are needed in the future.

A general problem for MRAM devices is the fact that the MRAM cells are programmed by programming currents in the wordlines and bitlines, which are usually in the milliamps (mA) range. Thus the programming currents create a significant voltage drop over the wordlines and bitlines during the programming operation. This creates problems. As for future process technologies, the supply voltage is steadily decreasing. However, there is a strong tendency that the voltage over the programmed wordlines and bitlines will increase due to increasing resistance in future technologies. The reason for the increase in resistance is that the widths of wordlines and bitlines decrease as semiconductor devices are scaled down to smaller dimensions. Additionally, there is typically a tendency for wordlines and bitlines to become longer in order to increase area efficiency of a memory. For future MRAM chips, it will be difficult to supply sufficiently high voltages in order to create necessary programming currents.

### SUMMARY OF THE INVENTION

In accordance with one aspect of the present invention, an apparatus comprises a memory circuit that includes a magnetoresistive random access memory (MRAM) cell, and a charge pump circuit electrically coupled to the memory circuit. The memory circuit and at least a first portion of the charge pump circuit are fabricated on a single semiconductor chip. A second portion of the charge pump circuit is external to the semiconductor chip and includes at least one capacitor. Both the second portion of the charge pump circuit and the semiconductor chip are packaged in a chip package.

In accordance with another aspect of the present invention, the semiconductor chip is packaged in a chip package, and the second portion of the charge pump circuit, which is external to the chip package, is electrically coupled to the memory circuit.

In accordance with another aspect of the present invention, a method of forming an apparatus includes forming a memory circuit comprising a MRAM cell. A charge pump circuit is electrically coupled to the memory circuit. In the preferred embodiments, the method further includes fabricating the memory circuit and at least a first portion of the charge pump circuit on a single semiconductor chip. The charge pump also includes a second portion with at least one capacitor. The semiconductor chip is packaged in a chip package. The second portion of the charge pump circuit is external to the chip package and electrically coupled to the first portion of the charge pump circuit.

In accordance with yet another aspect of the present invention, the second portion of the charge pump circuit is packaged in the chip package.

Advantages of embodiments of the present invention include reducing chip area cost and resolving the conflict of increasing programming current requirement and decreasing operation voltage supply.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a perspective view of a prior art MRAM device having magnetic stack memory cells arranged in an array, with wordlines and bitlines disposed below and above each memory cell for accessing the memory cells;

FIGS. 2A through 2C illustrate a single MRAM cell and the currents used to program the cell;

FIG. 3 illustrates a charge pump circuit that can be used to raise a circuit supply voltage to an MRAM programming voltage;

FIG. 4 illustrates a perspective view of a preferred embodiment of the present invention, wherein capacitors of a charge pump circuit are external to a chip package;

FIG. 5 illustrates a schematic view of an embodiment combining the charge pump circuit shown in FIG. 3 and the embodiment shown in FIG. 4; and

FIG. 6 illustrates a perspective view of another preferred embodiment of the present invention, wherein capacitors of a charge pump circuit are fabricated inside a chip package.

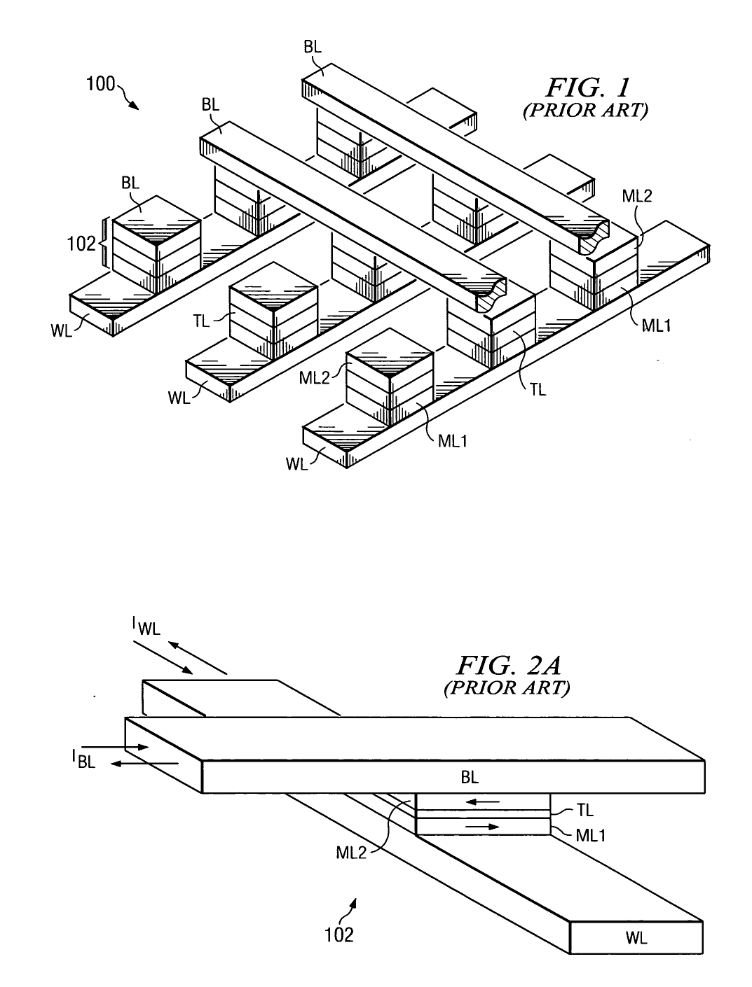

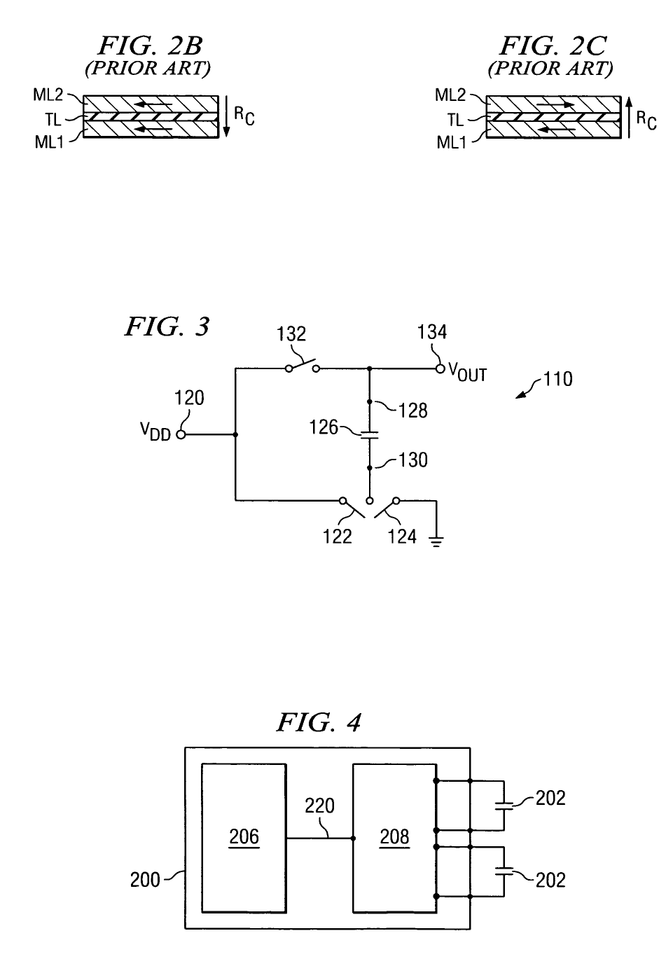

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

One way to resolve the conflict of the increasing difference between the MRAM programming voltage and circuit operation voltage is to use charge pumps to raise voltages. Through a charge pump, a circuit operation voltage can be pumped up to a desired programming voltage. An example of a simple charge pump 110 is illustrated in FIG. 3. The Charge pump 110 comprises three switches 122, 124, 132 and a capacitor 126. As will be discussed below, switches 122, 124, 132 are preferably formed on the integrated circuit along with MRAM cells while the capacitor 126 is external to the substrate. During a first clock phase, switches 124 and 132 are closed and switch 122 is opened, causing the capacitor 126 to be charged to a circuit supply voltage V_{DD}, which is supplied at an input node 120. During a second phase, the switches 124 and 132 are opened, and switch 122 is then closed, thus the bottom plate of the capacitor 126 assumes a potential V_{DD}. Since the capacitor 126 maintains its charge of V_{DD}*C from the first phase, the output voltage Vₒᵤₜ at an output node 134 can be derived from:
(Vₒᵤₜ−V_{DD})*C=V_{DD}*C [Eq. 1]
or
Vₒᵤₜ=2*V_{DD} [Eq. 2]

Thus, an output voltage Vₒᵤₜ that is twice the circuit supply voltage V_{DD} is generated. Output voltage Vₒᵤₜ may then be used as a high voltage supply. The charge pump 110 illustrated in FIG. 3 is very simple and is only used to explain the mechanism of charge pumps. In order to accommodate different requirements, many variations of charge pumps are designed, the number of capacitors and capacitances of the capacitors may vary. Each variation of the charge pumps, however, involves at least one, and preferably more than one, capacitor. The level of the output voltage Vₒᵤₜ and an output current of a charge pump are strongly dependent on the value of the capacitors. For example, big capacitors produce greater output currents, and small capacitors produce smaller output currents.

Charge pumps have been used in electrically erasable programmable read only memories (EEPROM) memories. Internal charge pump circuits have been built in the periphery of the cell arrays of the memory chips, creating programming voltages from the supply voltages of the chips. For internal charge pump circuits, switches are typically implemented using metal-oxide-semiconductor (MOS) devices, and capacitors are typically formed of MOS devices with their respective source and drain shorted. Capacitances of the internal capacitors are generally proportional to the area of the MOS device and thus are small. Therefore, the programming current that can be provided by an internal charge pump is small. However, an internal charge pump can provide sufficient programming current to EEPROM memories, mainly because the programming current of an EEPROM cell is in the order of about 1 nA. Charge pump circuits that can provide currents in μA range can be cost efficiently designed on chip.

For MRAM memories, however, the charge pump approach using on-chip capacitors is not readily usable. MRAM memories require programming currents in the milliamps (mA) range and thus significantly larger capacitors have to be built, which in turn consumes a large amount of chip area, making the charge pump solution unrealistic. An alternative solution is using multiple supply voltages, wherein a higher supply voltage may be used to supply the programming operation of the MRAM components, and a lower supply voltage may be used by remaining components that can be operated at lower voltage levels. However, this solution involves higher cost and more complicated circuit designs.

A schematic view of the preferred embodiment of the present invention solving the above-discussed problem is illustrated in FIG. 4. An MRAM chip 200 comprises MRAM cells 206 (e.g. an MRAM array) and a first portion 208 of a charge pump circuit. The charge pump circuit uses the voltage supply V_{DD} of the chip as an input voltage and generates an output voltage Vₒᵤₜ suitable for the MRAM programming. The output voltage Vₒᵤₜ is supplied to the MRAM array 206 for programming the MRAM cells through a connection 220. Preferably, switches, which are included in the first portion 208 of the charge pump circuit, are fabricated on the MRAM chip 200, and the capacitors 202 of the charge pump circuit are external to the MRAM chip 200.

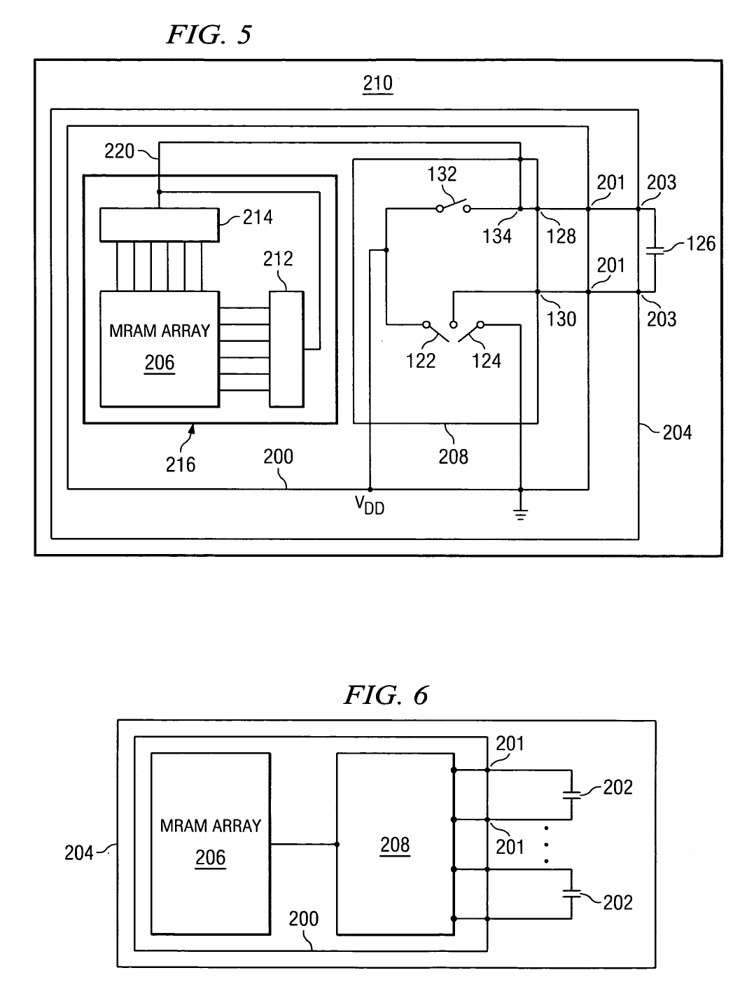

FIG. 5 illustrates an example of the preferred embodiment referred to in FIG. 4, where the charge pump 110 referred to in FIG. 3 is used to explain how external capacitors are connected. Switches 122, 124 and 132 of the exemplary charge pump 110 and MRAM cells 206 are fabricated on the same semiconductor substrate (sometimes referred as chip) 200, while capacitor 126 is external to the chip 200 (e.g. not formed on the same integrated circuit). Nodes 128 and 130 are preferably coupled to contact pads 201 of the MRAM chip 200. The MRAM chip 200 is enclosed in a chip package 204 and the contact pads 201 are further coupled to external pins 203 of the chip package 204. Preferably, when the chip package 204 is assembled on a circuit board 210, the external capacitor 126 may be attached to the circuit board 210 and electrically coupled to the external pins 203 of the chip package 204. The output voltage Vₒᵤₜ of the charge pump circuit is supplied to an MRAM circuit 216 through a connection 220. In an exemplary voltage distribution scheme, Vₒᵤₜ is distributed to a wordline selection circuit 212 and a bitline selection circuit 214, and Vₒᵤₜ is further distributed to selected wordlines and bitlines of the MRAM array 206. Through such a design, a charge pump circuit can have capacitors with very high capacitance, and provide high programming currents without sacrificing chip area.

One skilled in the art will realize that a practical charge pump may involve multiple capacitors 202, as illustrated in FIG. 4, and these capacitors may have different capacitance values. Since some of the small capacitors may have low capacitances requiring less area, in alternative embodiments, these small capacitors may be fabricated on the MRAM chip 200, while capacitors with high capacitances are external to the MRAM chip 200.

FIG. 6 illustrates another preferred embodiment of the present invention, which includes an MRAM chip 200 including MRAM cells 206 and a first portion 208 of a charge pump circuit. Capacitors 202, which form a second portion of the charge pump circuit, are external to the MRAM chip 200 and electrically coupled to the first portion 208 through contact pads 201. Capacitors 202 may be in any appropriate form such as individual capacitors, capacitors built on separate semiconductor chips, etc., providing that they have desired capacitance values. The MRAM chip 200 and capacitors 202 are packaged in a chip package 204. In an embodiment where capacitors 202 are fabricated on separate capacitor chip(s), the capacitor chip(s) and MRAM chip 200 can be packaged in the form of commonly used stacked dies, and thus no customized packaging is required.

The preferred embodiments of the present invention have some advantageous features. Due to increasingly high numbers of MRAM cells built on one memory chip, higher programming currents may be required and thus built-in capacitors may require increasingly larger areas. By using external capacitors, the capacitances are not limited by the chip area available, and thus capacitors with very big capacitance can be built. This is particularly useful for concurrent programming wherein multiple MRAM cells are programmed at the same time, thereby requiring greater current. Additionally, the voltage supply for programming the MRAM is obtained by the use of a charging pump for the circuit operation voltage of the chip, therefore, no secondary voltage supply is required.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An apparatus comprising:
a memory circuit comprising a magnetoresistive random access memory (MRAM) cell; and
a charge pump circuit electrically coupled to the memory circuit wherein the memory circuit and at least a first portion of the charge pump circuit are fabricated on a single semiconductor chip, wherein a second portion of the charge pump circuit is external to the semiconductor chip, and wherein at least one capacitor of the charge pump circuit is in the second portion.

2. The apparatus of claim 1 wherein the semiconductor chip and the second portion of the charge pump circuit are packaged in a single chip package.

3. The apparatus of claim 1 wherein the semiconductor chip is packaged in a chip package and wherein the second portion of the charge pump circuit is external to the chip package.

4. The apparatus of claim 1 further comprising a capacitor in the first portion of the charge pump circuit.

5. The apparatus of claim 1 wherein the charge pump circuit has all capacitors in the second portion external to the semiconductor chip.

6. A semiconductor chip comprising:
a semiconductor substrate;
a memory circuit formed on the semiconductor substrate, the memory circuit comprising an array of magnetoresistive random access memory (MRAM) cells; and
a portion of a charge pump circuit formed on the semiconductor substrate and electrically coupled to the memory circuit; and
an external connection node coupled to the portion of the charge pump circuit such that an external capacitor can be coupled to the portion of the charge pump circuit through the external connection node.

7. The semiconductor chip of claim 6 wherein the portion of the charge pump circuit includes a capacitor.

8. The semiconductor chip of claim 6 wherein the portion of the charge pump circuit does not include any capacitor.

9. The semiconductor chip of claim 6 wherein the portion of the charge pump circuit is not operable as a charge pump circuit without being coupled to an external capacitor.

10. The semiconductor chip of claim 6 in combination with the external capacitor, wherein the external capacitor is coupled to the portion of the charge pump circuit through the external connection node.

11. A method of forming an apparatus, the method comprising:
providing a substrate;
forming an array of magnetoresistive random access memory (MRAM) cells in the substrate;
forming other circuitry in the substrate, the other circuitry including a portion of a charge pump that is electrically coupled to the other circuitry and MRAM cells; and
coupling at least one external capacitor to the portion of the charge pump, the at least one external capacitor being coupled through a contact pad on the substrate.

12. The method of claim 11 further comprising packaging the substrate.

13. The method of claim 12 further comprising packaging the at least one external capacitor with the substrate.

14. The method of claim 12 wherein the at least one external capacitor is coupled to the portion of the charge pump circuit after packaging the substrate.

15. A method of programming an MRAM circuit, the method comprising:
providing a first supply voltage to a substrate comprising an MRAM cell;
charging at least one external capacitor;
raising the first supply voltage to a second supply voltage by using a charge pump circuit fabricated on the substrate wherein the charge pump circuit comprises the at least one external capacitor; and
generating a current using the second supply voltage and supplying the current to a wordline and/or a bitline of the MRAM cell and thereby programming the MRAM cell.

16. The method of claim 15 further comprising discharging the at least one external capacitor to generate the current.
